(19) United States
(12) Patent Application Publication
(10) Pub. No.: US 2018/0354781 A1
(43) Pub. Date: Dec. 13, 2018

(54) BIOSENSOR PACKAGE STRUCTURE AND MANUFACTURING METHOD THEREOF

(71) Applicant: Silicon Optronics, Inc., Hsinchu (TW)

(72) Inventor: Chi-Hsing HSU, Hsinchu (TW)

(21) Appl. No.: 15/855,097

(22) Filed: Dec. 27, 2017

(30) Foreign Application Priority Data
Jun. 12, 2017 (TW) 106119427

(51) Int. Cl. B81B 7/00; B81C 1/00; H01L 23/00; B01L 3/00

(52) U.S. Cl. CPC B81B 7/0006; B01L 2300/04; B81C 1/00888; B81C 1/00206; H01L 24/19; H01L 24/20; H01L 24/96; B01L 3/508; B81B 2201/0214; H01L 2224/214; H01L 2224/95001; B01L 2300/0819; B01L 2200/12; B01L 2200/02; B81C 1/00095

(57) ABSTRACT

A biosensor package structure is provided. The biosensor package structure includes a protection layer and a redistribution layer disposed over the protection layer. The protection layer has a plurality of openings exposing the redistribution layer. The biosensor package structure includes at least one die disposed over the protection layer and the redistribution layer, a plurality of pads disposed on a lower surface of the die, and a plurality of vias disposed between the pads and the redistribution layer. The biosensor package structure includes a dielectric material disposed over the protection layer and the redistribution layer and adjacent to the die, pads and vias. The biosensor package structure further includes at least one biosensing region at the top portion of the die. The top surfaces of the pads are disposed at a level that is lower than the top surface of the biosensing region and higher than the bottom surface of the die.

### CROSS REFERENCE TO RELATED APPLICATIONS

This application claims priority of Taiwan Application No. 106119427, filed on Jun. 12, 2017, the entirety of which is incorporated by reference herein.

### BACKGROUND

### Technical Field

The disclosure relates to a biosensor package structure and a manufacturing method thereof.

### Description of the Related Art

Biosensors consist of molecular recognition elements and signal converting elements. Biosensors may convert chemical signals generated from the biochemical reaction to electrophysic signals for analysis. For example, biochips utilize micro-electro-mechanical systems (MEMS) technologies to implant probes in chips, and then biochips may conduct various biochemical analyses based on characteristic biology conjunctions. Biochips may be applied to subjects such as genes, proteins, cells and tissues and in fields such as biomedical research, disease diagnosis, food pathogen detection, environmental analysis acid characterization, and so on. The biochip industry is flourishing due to the advantages of biochips being portable, highly sensitive and specific, providing a quick analysis, and requiring only small quantities of samples and agents.

In existing biochip package structures, the reaction region and the electrical connection region of the biochip are mostly integrated on the surface of the substrate by wire bonding. For example, the reaction region is adjacent to the pad and the conductive wire, and the reaction region, the pad and the conductive wire are disposed on the surface of the package structure. However, in such package structures, the pad and the conductive wire are easily corroded by the strong alkali reaction solutions that are applied to the biochip, and thus the performance the biochip can be affected. In addition, the electrical connecting elements such as the pads and the conductive wires and so on that are disposed on the surface of the substrate also limit the area of the reaction region of the biochip.

Generally, in biochip package structures, the wafer is cut to form dies after the biomaterial is coated on the wafer, and then the subsequent packaging process of the dies can be performed. Nevertheless, the biomaterial (biocoating) coating used in the biochip can easily be affected by temperature changes in the subsequent steps of the packaging process, e.g. the steps of etching, deposition, and so on.

Accordingly, for biochip researchers, it is desirable to develop a package structure having a simple structure to enable the improved performance of the biochip.

### SUMMARY

In accordance with some embodiments, the present disclosure provides a biosensor package structure including a protection layer, a redistribution layer, at least one die, a plurality of pads, a plurality of vias, a dielectric material, and at least one biosensing region. The redistribution layer is disposed over the protection layer. The protection layer has a plurality of openings that expose the redistribution layer. The die is disposed over the protection layer and the redistribution layer. The pads are disposed on a lower surface of the die. The vias are disposed between the plurality of pads and the redistribution layer for electrical connection. The dielectric material is disposed over the protection layer and the redistribution layer and is adjacent to the die, the plurality of pads and the plurality of vias. The biosensing region is disposed at the top portion of the die. The top surfaces of the pads are disposed at a level that is lower than the top surface of the biosensing region and higher than the bottom surface of the die.

In accordance with some embodiments, the present disclosure provides a method for manufacturing a biosensor package structure including: providing a first carrier substrate; forming a least one die over the first carrier substrate, wherein the die comprises at least one biosensing region that is formed at the bottom region of the die and a plurality of pads that are formed on the upper surface of the die, wherein the biosensing region is in contact with the first carrier substrate, and the bottom surfaces of the plurality of pads are disposed at a level that is higher than the bottom surface of the biosensing region and lower than the top surface of the die; forming a dielectric material covering the first carrier substrate and the die; performing a planarization process to expose the top surface of the die; patterning the dielectric material to firm a plurality of first openings that expose the top surfaces of the plurality of pads: filling a conductive material in the plurality of first openings to form a plurality of vias that extend through the dielectric material; forming a redistribution layer and a protection layer over the dielectric material, wherein the redistribution layer is in contact with the plurality of vias so as to be electrically coupled to the plurality of pads; and removing the first carrier substrate to expose the biosensing region.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1 illustrates a process flow of the method for manufacturing a biosensor package structure in accordance with some embodiments of the present disclosure;

FIG. 2 illustrates a cross-sectional view of the biosensor package structure in the intermediate stage of the manufacturing of the biosensor package structure in accordance with some embodiments of the present disclosure;

FIG. 3 illustrates a cross-sectional view of the biosensor package structure in the intermediate stage of the manufacturing of the biosensor package structure in accordance with some embodiments of the present disclosure:

FIG. 4 illustrates a cross-sectional view of the biosensor package structure in the intermediate stage of the manufacturing of the biosensor package structure in accordance with some embodiments of the present disclosure;

FIG. 5 illustrates a cross-sectional view of the biosensor package structure in the intermediate stage of the manufacturing of the biosensor package structure in accordance with some embodiments of the present disclosure:

FIG. 6 illustrates a cross-sectional view of the biosensor package structure in the intermediate stage of the manufacturing of the biosensor package structure in accordance with some embodiments of the present disclosure;

FIG. 7 illustrates a cross-sectional view of the biosensor package structure in the intermediate stage of the manufacturing of the biosensor package structure in accordance with some embodiments of the present disclosure;

FIG. 8 illustrates a cross-sectional view of the biosensor package structure in the intermediate stage of the manufacturing of the biosensor package structure in accordance with some embodiments of the present disclosure;

FIG. 9 illustrates a cross-sectional view of the biosensor package structure in accordance with some embodiments of the present disclosure.

### DETAILED DESCRIPTION

The biosensor package structure of the present disclosure and the manufacturing method thereof are described in detail in the following description. In the following detailed description, for purposes of explanation, numerous specific details and embodiments are set forth in order to provide a thorough understanding of the present disclosure. The specific elements and configurations described in the following detailed description are set forth in order to clearly describe the present disclosure. It will be apparent, however, that the exemplary embodiments set forth herein are used merely for the purpose of illustration, and the inventive concept may be embodied in various forms without being limited to those exemplary embodiments. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments. In addition, in this specification, expressions such as “a first material layer disposed on over a second material layer”, may indicate the direct contact of the first material layer and the second material layer, or it may indicate a non-contact state with one or more intermediate layers between the first material layer and the second material layer. In the above situation, the first material layer may not be in direct contact with the second material layer.

In addition, in this specification, relative expressions are used. For example, “lower”, “bottom”, “higher” or “top” are used to describe the position of one element relative to another. It should be appreciated that if a device is flipped upside down, an element that is “lower” will become an element that is “higher”.

It should be understood that, although the terms “first”, “second”, “third” etc. may be used herein to describe various elements, components, regions, layers, portions and/or sections, these elements, components, regions, layers, portions and/or sections should not be limited by these terms. These terms are only used to distinguish one element, component, region, layer, portion or section from another region, layer or section. Thus, a first element, component, region, layer, portion or section discussed below could be termed a second element, component, region, layer, portion or section without departing from the teachings of the present disclosure.

It should be understood that, this description of the exemplary embodiments is intended to be read in connection with the accompanying drawings, which are to be considered part of the entire written description. The drawings are not drawn to scale. In addition, structures and devices are shown schematically in order to simplify the drawing.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In addition, in some embodiments of the present disclosure, terms concerning, attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

In accordance with the biosensor package structure provided in some embodiments of the present disclosure, the electrical connecting elements that are coupled to the biosensor are disposed at a position which is lower than the surface of the reaction region of the biosensor. In particular, in accordance with the biosensor package structure provided in some embodiments of the present disclosure, the pads for electrical connection are disposed below a portion of the die that includes the biosensor, and the pads are substantially embedded in the dielectric material of the package structure. In this way, the reaction area of the biosensing region may be increased, and the corrosion of conductive wire resulted from the alkali reaction solution in the wire-bonding package structure may be reduced.

In addition, in the method for manufacturing the biosensor package structure of the present disclosure, the wafer-leveled or panel-leveled biomaterial coating may be conducted after the packaging process of the dies, and then a cutting process may be performed to obtain the final product of the package structure. Accordingly, the damage on the biomaterial coating caused by the temperature changes in the packaging process may be reduced.

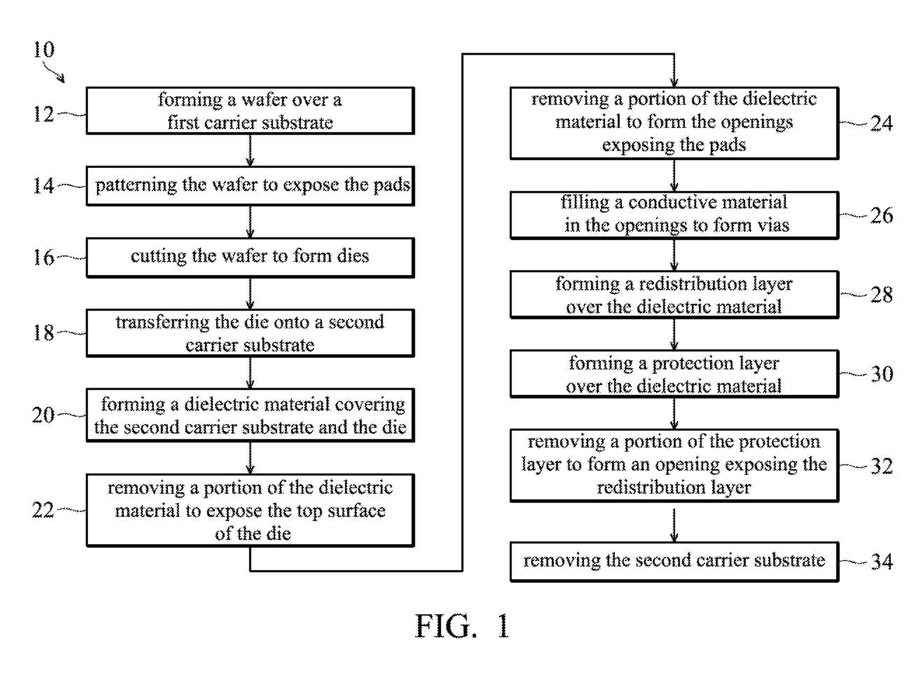

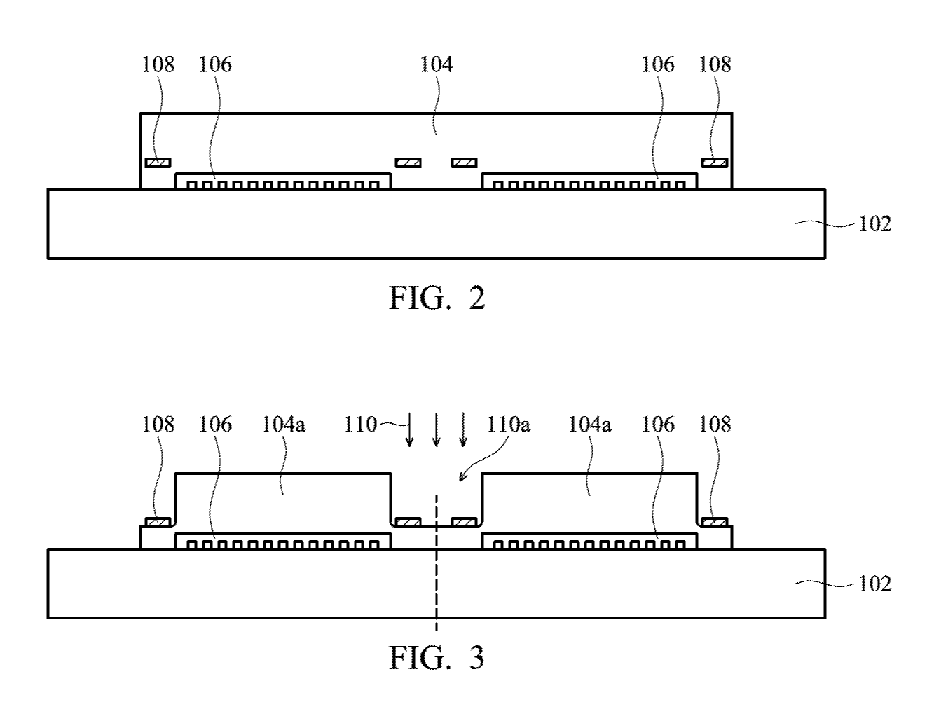

FIG. 1 illustrates a process flow of the method 10 for manufacturing a biosensor package structure in accordance with some embodiments of the present disclosure. It should be understood that, additional operations may be provided before, during, and after processes in the method 10 for manufacturing a biosensor package structure. In some embodiments of the present disclosure, some of the operations described below may be replaced or eliminated. The order of the operations/processes may be interchangeable. In some embodiments of the present disclosure, additional features may be added to the biosensor package structure. In another embodiment of the present disclosure, some of the features described below may be replaced or eliminated. FIGS. 2-9 illustrate the cross-sectional views of the biosensor package structure in different stages of the method 10 in accordance with some embodiments of the present disclosure.

First, referring to FIG. 1 and FIG. 2, the method 10 for manufacturing the biosensor package structure starts in step 12. The wafer 104 is formed over a first carrier substrate 102. The wafer 104 includes the biosensing regions 106 and the pads 108 formed therein. As shown in FIG. 2, the biosensing regions 106 may be disposed at the bottom of the wafer 104. In other words, the biosensing regions 106 are disposed between the first carder substrate 102 and the wafer 104. Moreover, the pads 108 may be embedded in the wafer 104, and are disposed at a level that is higher than the biosensing regions 106.

The first carrier substrate 102 may further include an adhesive layer (not illustrated) formed thereon. The wafer 104 may temporarily be affixed to the first carrier substrate 102 by the adhesive layer. The first carrier substrate 102 may be made of, but is not limited to, a silicon substrate, a glass substrate, a polymer substrate, a polymer-based substrate, any other suitable substrate, or a combination thereof.

The material of the wafer 104 may include semiconductor materials or any other suitable substrate. In some embodiments of the present disclosure, the material of the wafer 104 may include elemental semiconductor materials such as monocrystalline, polycrystalline or amorphous silicon (Si), germanium (Ge), or a combination thereof. In some embodiments of the present disclosure, the material of the wafer 104 may include compound semiconductor materials such as silicon carbide (SiC), gallium arsenide (GaAs), gallium phosphide (GaP), indium phosphide (InP), indium arsenide (InAs) and so on. In some embodiments of the present disclosure, the material of the wafer 104 may include alloy semiconductor materials such as silicon germanium (SiGe), aluminum gallium arsenide (AlGaAs), gallium indium arsenide (GaInAs), gallium indium phosphide (GaInP), gallium arsenide phosphide (GaAsP) and so on.

As shown in FIG. 2, one side of the biosensing region 106 is in contact with the surface of the first carrier substrate 102. The biosensing region 106 may be, but is not limited to, a biochip or any other elements used for sensing biochemical reactions. The biochip may be used for the treatment or the analysis of biosamples. One with ordinary skill in the art will readily understand that any suitable biochips may be chose according to needs. For example, the biochip may include, but is not limited to, gene chips such as gene microarrays, oligonucleotide microarrays, cDNA microarrays, DNA chips and so on, protein chips, carbohydrate chips, tissue chips, cell-based microarrays, microfluidic chips or Lab-on-chips.

As described above, the pads 108 are disposed within the wafer 104 for electrical connection. In some embodiments of the present disclosure, the pad 108 may be any metal layer (e.g. M0, M1, M2 and so on) in the interconnection structure of the wafer 104. The materials of the pad 108 may include copper (Cu), copper alloys, aluminum (Al), aluminum alloys, molybdenum (Mo), molybdenum alloys, tungsten (W), tungsten alloys, gold (Au), gold alloys, chromium (Cr), chromium alloys, nickel (Ni), nickel alloys, platinum (Pt), platinum alloys, titanium (Ti), titanium alloys, iridium (Ir), iridium alloys, rhodium (Rh), rhodium alloys, titanium nitride (TiN), tantalum nitride (TaN), nickel silicide (NiSi), cobalt silicide (CoSi), tantalum carbide (TaC), tantalum silicide nitride (TaSiN), tantalum carbide nitride (TaCN), titanium aluminide (TiAl), titanium aluminide nitride (TiAlN), any other suitable conductive materials or a combination thereof.

Next, referring to FIG. 1 and FIG. 3, in step 14, a patterning process 110 is performed on the wafer 104 to remove portions of the wafer 104 that are located above the pads 108 and to expose the pads 108. In some embodiments of the present disclosure, one or more photolithography and etching processes are used to partially remove the wafer 104. In some embodiments of the present disclosure, the etching process includes a dry etching process, a wet etching process, any other suitable etching processes or a combination thereof. For example, the dry etching process may include reactive ion etch (RIE), plasma etch and so on.

Still referring to FIG. 1 and FIG. 3, in step 16, a cutting process is performed on the wafer 104 to form a plurality of dies 104a. In some embodiments of the present disclosure, the pads 108 may be located on the cutting line of the wafer 104. In some embodiments of the present disclosure, the dies 104a that are formed after the cutting process may include at least one biosensing region 106 disposed therein and a plurality of pads 108 disposed in the recess 110a that is formed by the etching process 110. It should be understood that, although the die 104a include one biosensing region 106 and two pads 108 in the illustrated figure, one may have suitable amounts of the biosensing region 106 and the pads 108 disposed according to needs. In addition, the cutting process may include mechanical cutting, laser cutting, any other suitable cutting processes or a combination thereof.

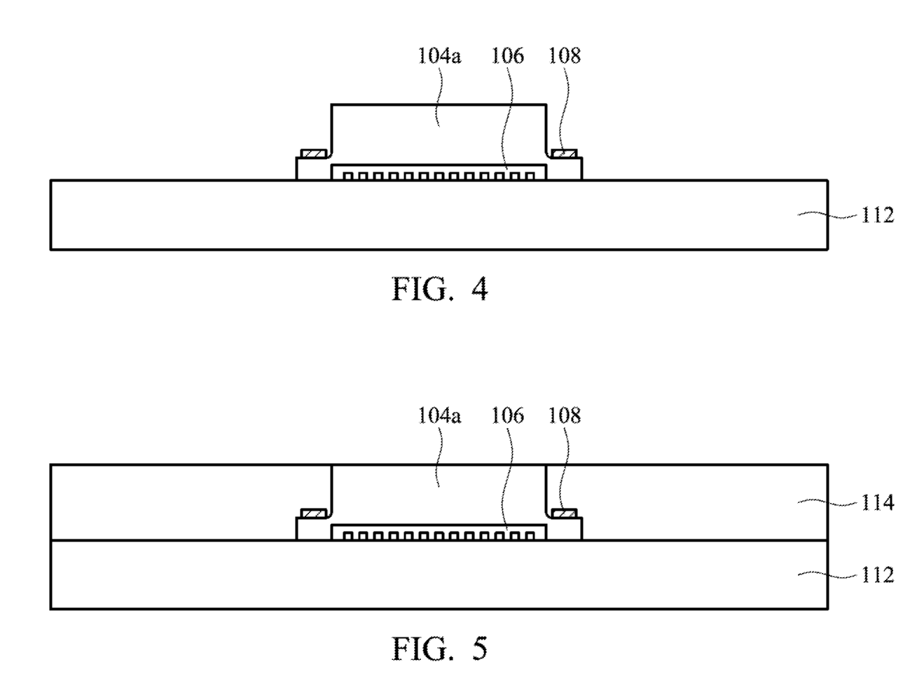

Next, referring to FIG. 1 and FIG. 4, in step 18, the die 104a that is formed after the cutting in step 16 is transferred onto a second carrier substrate 112 to perform the subsequent packaging process of the dies. In some embodiments of the present disclosure, the dies 104a may be arranged on the second carrier substrate 112 with a suitable dimension or pitch to form a wafer or a panel that is used in the subsequent process of packaging (e.g., steps 20 to 34 and so on). However, only one die 104a is illustrated in the figure for simplicity.

In addition, as shown in FIG. 4, the die 104a is disposed over the second carrier substrate 112. The bottom portion of the die 104a includes the biosensing region 106. In other words, the biosensing region 106 is located between the second carrier substrate 112 and the die 104a. One side of the biosensing region 106 is in contact with the second carrier substrate 112. Moreover, the pads 108 are disposed at a level that is higher than the biosensing region 106. In particular, the bottom surfaces of the pads 108 may be disposed at any level that is higher than the bottom surface of the biosensing region 106 and is lower than the top surface of the die 104a. In some embodiments of the present disclosure, the bottom surfaces of pads 108 may be disposed at a level that is higher than the top surface of the biosensing region 106 and lower than the top surface of the die 104a.

The second carrier substrate 112 may further include an adhesive layer (not illustrated). The die 104a may temporarily be affixed to the second carrier substrate 112 by the adhesive layer. The second carrier substrate 112 may be made of, but is not limited to, a silicon substrate, a glass substrate, a polymer substrate, a polymer-based substrate, any other suitable substrate, or a combination thereof. The materials of the second carrier substrate 112 may be the same or different from that of the first carrier substrate 102.

Next, referring to FIG. 1 and FIG. 5, in step 20, a dielectric material 114 is formed to cover the second carrier substrate 112, the die 104a and the pads 108. In some embodiments of the present disclosure, the dielectric material 114 may fully cover the second carrier substrate 112, the die 104a and the pads 108 so that the die 104a and the pads 108 are embedded in the dielectric material 114. The dielectric material 114 may include epoxy, phenol resin, FR-4 (which is a composite material composed of woven fiberglass cloth with an epoxy resin hinder that is flame resistant), silicone, any other suitable dielectric materials or a combination thereof. In addition, the dielectric material 114 may be formed by spin coating, transfer molding, injection molding, any other suitable processes or a combination thereof.

Next, referring to FIG. 1 and FIG. 5, in step 22, a planarization process is performed to partially remove the dielectric material 114 until the top surface of the die 104 is exposed. In some embodiments of the present disclosure, the top surface of the planarized dielectric material 114 is substantially level with the top surface of the die 104. In addition, the planarization process may include a chemical mechanical planarization process, a polishing process, an etching process, any other applicable process, or a combination thereof.

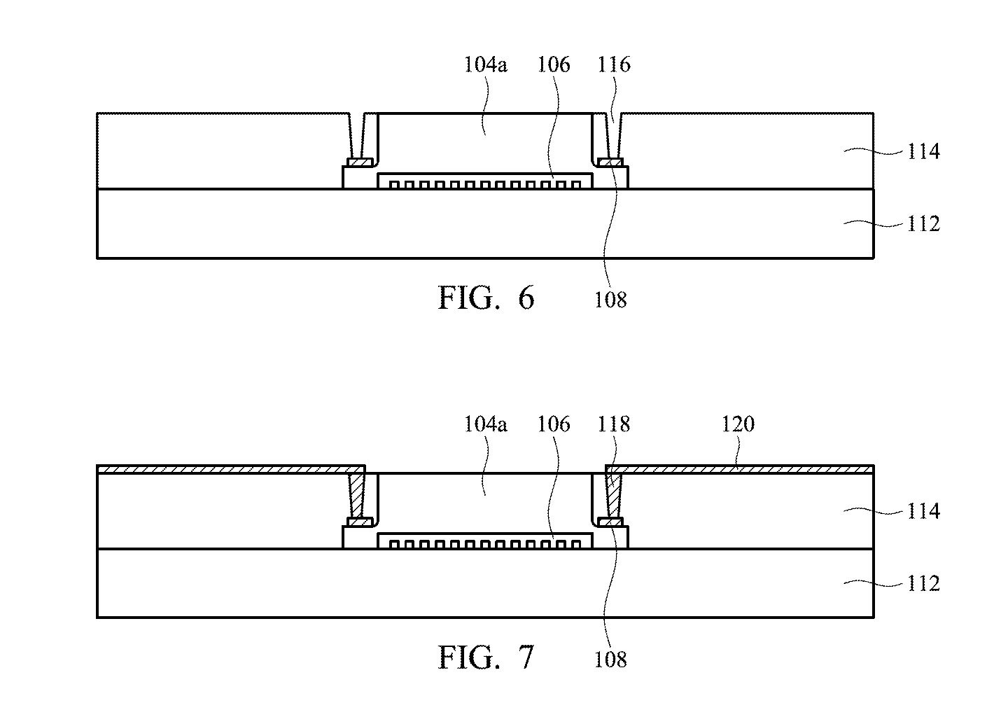

Next, referring to FIG. 1 and FIG. 6, in step 24, the dielectric material 114 is patterned to remove portions of the dielectric materials 114 that are located above the pads 108 and to form the openings 116 that expose the top surfaces of the pads 108. In some embodiments of the present disclosure, one or more photolithography and etching processes are used to partially remove the dielectric materials 114 to form the opening 116. In some embodiments of the present disclosure, the etching process includes a dry etching process, a wet etching process, any other suitable etching processes, or a combination thereof. For example, the dry etching process may include reactive ion etch (RIE), plasma etch and so on.

Next, referring to FIG. 1 and FIG. 7, in step 26, the conductive materials are filled in the openings 116 to form the vias 118. The vias 118 extends through the dielectric layer 114 from the pads 108. The conductive materials may include copper (Cu), copper alloys, aluminum (Al), aluminum alloys, molybdenum (Mo), molybdenum alloys, tungsten (W), tungsten alloys, gold (Au), gold attire, chromium (Cr), chromium alloys, nickel (Ni), nickel alloys, platinum (Pt), platinum alloys, titanium (Ti), titanium alloys, iridium (Ir), iridium alloys, rhodium (Rh), rhodium alloys, titanium nitride (TiN), tantalum nitride (TaN), nickel silicide (NiSi), cobalt silicide (CoSi), tantalum carbide (TaC), tantulum silicide nitride (TaSiN), tantalum carbide nitride (TaCN), titanium aluminide (TiAl), titanium aluminide nitride (TiAlN) any other suitable conductive materials or a combination thereof.

In some embodiments of the present disclosure, sputtering, evaporation, an electroplating process, an electroless plating process, atomic layer deposition (ALD), physical vapor deposition (PVD), chemical vapor deposition (CVD), any other applicable process, or a combination thereof may be used to form the conductive material in the openings 116.

Next, referring to FIG. 1 and FIG. 7, in step 28, a redistribution layer 120 is formed over the planarized dielectric layer 114. The redistribution layer 120 is in contact with the vias 118 to electrically connect to the pads 108. It is understood that the pads 108, the vias 118 and the redistribution layer 120 may serve as the conductive routes of the biosensor package structure.

The redistribution layer 120 may be formed by conductive materials. The conductive materials may include copper (Cu), copper alloys, aluminum (Al), aluminum alloys, molybdenum (Mo), molybdenum alloys, tungsten (W), tungsten alloys, gold (Au), gold alloys, chromium (Cr), chromium alloys, nickel (Ni), nickel alloys, platinum (Pt), platinum alloys, titanium (Ti), titanium alloys, iridium (Ir), iridium alloys, rhodium (Rh), rhodium alloys, titanium nitride (TiN), tantalum nitride (TaN), nickel silicide (NiSi), cobalt silicide (CoSi), tantulum carbide (TaC), tantulum silicide nitride (TaSiN), tantalum carbide nitride (TaCN), titanium aluminide (TiAl), titanium aluminide nitride (TiAlN), any other suitable conductive materials or a combination thereof. In some embodiments of the present disclosure, sputtering, evaporation, an electroplating process, an electroless plating process, a photolithography process, any other applicable process, or a combination thereof may be used to form the redistribution layer 120.

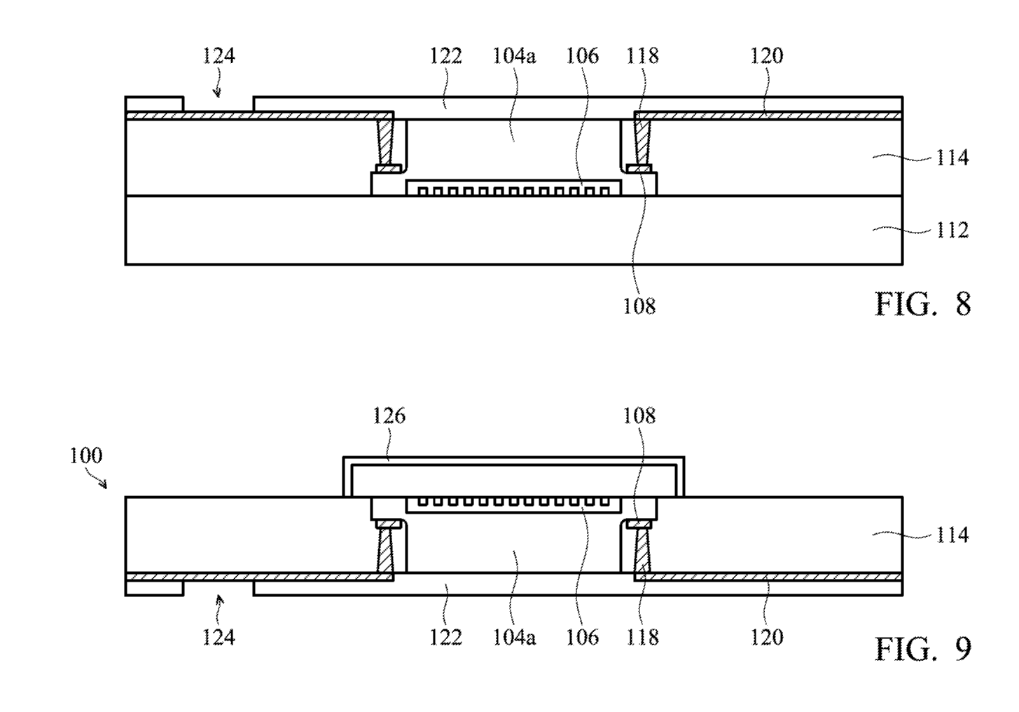

Next, referring to FIG. 1 and FIG. 8, in step 30, a protection layer 122 is formed over the dielectric material 114 and the die 104a. The protection layer 122 covers the redistribution layer 120 and the die 104a. In particular, the protection layer 122 is in contact with a portion of the redistribution layer 120, a portion of the dielectric material 114 and a portion of the die 104a. The protection layer 122 may be a solder mask or a solder resist and may be formed of the solder resist materials that are known in the art. In some embodiments of the present disclosure, a coating process, a printing process, any other applicable process, or a combination thereof may be used to form the protection layer 122.

Next, in step 32, a patterning process is performed on the protection layer 122 to remove a portion of the protection layer 122 and to form an opening 124 that exposes the redistribution layer 120. In some embodiments of the present disclosure, one or more photolithography and etching processes are used to partially remove the protection layer 122. In some embodiments of the present disclosure, the etching process includes a dry etching process, a wet etching process, any other suitable etching processes, or a combination thereof. For example, the dry etching process may include reactive ion etch (RIE), plasma etch and so on.

Next, referring to FIG. 1 and FIG. 9, in step 34, the second carrier substrate 112 is removed to expose the biosensing region 106, and the package structure is inverted. In some embodiments of the present disclosure, after step 34, a wafer-level or panel-level coating of biomaterials may be performed on the top surface of the biosensing region 106 and a cutting process may be performed on the wafer or panel used for packaging, i.e. the wafer or panel that is formed in step 18, according to needs. Then, the final product of the biosensor package structure with a suitable size may be obtained. The above biomaterials may include any known materials that are used in the reactive coating of the biochips. The biosensor package structure that formed after the cutting process of the wafer or panel used for packaging may include a suitable amount of dies 104a according to needs. In some embodiments of the present disclosure, a biosensor package structure may include one die 104a. In some embodiments of the present disclosure, a biosensor package structure may include two or more dies 104a.

FIG. 9 illustrates a cross-sectional view of a completed biosensor package structure 100 in accordance with some embodiments of the present disclosure. As shown in FIG. 9, the pads 108 are disposed on a lower surface of the die 104 and contact the die 104a in the biosensor package structure 100. The pads 108 are disposed at a level that is lower than the biosensing region 106. The pads 108 are electrically connected to the redistribution layer 120 through the vias 118. In some embodiments of the present disclosure, the top surfaces of the pads 108 are disposed at a level that is lower than the top surface of the biosensing region 106 and the top surface of the die 104a. In some embodiments of the present disclosure, the top surfaces of the pads 108 are disposed at a level that is higher than the bottom surface of the die 104a and the bottom surface of the dielectric material 114. In some embodiments of the present disclosure, the top surfaces of the pads 108 are disposed at a level that is lower than the bottom surface of the biosensing region 106. In other words, the pads 108 are disposed between the top surface of the biosensing region 106 and the bottom surface of the die 104a.

As shown in FIG. 9, the top surface of the biosensing region 106 is substantially level with the top surfaces of the die 104a and the dielectric material 114. The die 104a, the pads 108 and the vias 118 are embedded in the dielectric material 114. In addition, the redistribution layer 120 may be coupled to an external signal processor (not illustrated) through the opening 124 so as to process the information generated from the reaction of the biosensing region 106.

On the other hand, a lid 126 may be further disposed over the dielectric material 114 to cover the die 104a and the biosensing region 106. The area of the lid 126 may be greater than the area of the top surface of the biosensing region. The lid 126 may provide protection for the reaction region of the biosensing region 106 and also provide the reaction space for the operation of biosensing region 106, e.g. the space for the biosamples and reaction agents. The material of the lid 126 may include glass, polymethyl methacrylate (PMMA), polydimethylsiloxane (PDMS), silicone, epoxy, any other suitable materials or a combination thereof.

One with ordinary skill in the art will readily understand that an inlet/outlet (not illustrated) may be further disposed on the biosensor package structure 100 to load or remove the biosamples or the reaction agents. For example, in some embodiments of the present disclosure, the biosamples or the reaction agents may be directed into the biosensing region 106 from the inlet and be removed from the outlet after completing all the processes such as treatments or analyses. In some embodiments of the present disclosure, a fluid reservoir (not illustrated) may be further disposed at the inlet as the fluid source.

To summarize the above, in accordance with the biosensor package structure provided in some embodiments of the present disclosure, the electrical connecting elements are disposed at a position which is lower than the surface of the reaction region of the biosensor. The pads are embedded in the dielectric material of the package structure and thus may prevent corrosion by the reaction agents used in the biosensor. In general wire-bonding chip packages, the electrical connecting elements are disposed on the surface of the package structure. In comparison with common chip packages, the electrical connecting elements of the biosensor package structure provided in the present disclosure will not occupy the area of the biosensing region. Moreover, the biosensor package structure of the present disclosure may provide an intact biosensing region on the surface and may increase the effective reaction area of the biosensing region. Therefore, the efficiency of the biosensor is improved.

In addition, in the method for manufacturing the biosensor package structure of the present disclosure, the wafer-leveled or panel-leveled biomaterial coating may be conducted after the packaging process of the dies, and then a cutting process may be performed to obtain the final product of the package structure. Accordingly, the damage to the biomaterial coating caused by the temperature changes in the packaging process may be reduced.

Although some embodiments of the present disclosure and their advantages have been described in detail, it should be understood that various changes substitutions and alterations can be made herein without departing from the spirit and scope of the disclosure as defined by the appended claims. For example, it will be readily understood by one of ordinary skill in the art that of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A biosensor package structure, comprising
a protection layer;
a redistribution layer disposed over the protection layer, wherein the protection layer has a plurality of openings that expose the redistribution layer;
at least one die disposed over the protection layer and the redistribution layer;
a plurality of pads disposed on a lower surface of the die;
a plurality of vias disposed between the plurality of pads and the redistribution layer for electrical connection;
a dielectric material disposed over the protection layer and the redistribution layer and adjacent to the die, the plurality of pads and the plurality of vias; and
at least one biosensing region disposed at the top portion of the die, wherein the top surfaces of the plurality of pads are disposed at a level that is lower than a top surface of the biosensing region and higher than a bottom surface of the die.

2. The biosensor package structure as claimed in claim 1, wherein the top surfaces of the plurality of pads are disposed at a level that is lower than a bottom surface of the biosensing region.

3. The biosensor package structure as claimed in claim 1, wherein the top surface of the biosensing region is substantially level with a top surface of the die.

4. The biosensor package structure as claimed in claim 1, wherein the die, the plurality of pads and the plurality of vias are embedded in the dielectric material.

5. The biosensor package structure as claimed in claim 1, wherein a top surface of the dielectric material is substantially level with the top surface of the biosensing region and the top surface of the die.

6. The biosensor package structure as claimed in claim 1, wherein the redistribution layer is coupled with a signal processor through the plurality of openings of the protection layer.

7. The biosensor package structure as claimed in claim 1, further comprising
a lid disposed over the dielectric material and covering the biosensing region.

8. A method for manufacturing a biosensor package structure, comprising
providing a first carrier substrate;
forming a least one die over the first carrier substrate, wherein the die comprises at least one biosensing region that is formed at a bottom region of the die and a plurality of pads that are formed on an upper surface of the die, wherein the biosensing region is in contact with the first carrier substrate, and the bottom surfaces of the plurality of pads are disposed at a level that is higher than the bottom surface of the biosensing region and lower than the top surface of the die;
forming a dielectric material coveting the first carrier substrate and the die:
performing a planarization process to expose the top surface of the die;
patterning the dielectric material to form a plurality of first openings that expose the top surfaces of the plurality of pads;
filling a conductive material in the plurality of first openings to form a plurality of vias that extend through the dielectric material;
forming a redistribution layer and a protection layer over the dielectric material, wherein the redistribution layer is in contact with the plurality of vias so as to be electrically coupled to the plurality of pads; and
removing the first carrier substrate to expose the biosensing region.

9. The method for manufacturing a biosensor package structure as claimed in claim 8, wherein the bottom surfaces of the plurality of pads are disposed at a level that is lower than the top surface of the biosensing region.

10. The method for manufacturing a biosensor package structure as claimed in claim 8, wherein the top surface of the die is substantially level with the top surface of the dielectric material after the planarization process.

11. The method for manufacturing a biosensor package structure as claimed in claim 8, wherein formation of the die is poor to the step of providing the first carrier substrate and comprises
providing a second carrier substrate;
forming a wafer on the second carrier substrate, wherein the wafer includes a plurality of biosensing regions and a plurality of pads formed therein;
patterning the wafer to remove a portion of the wafer that is located above the plurality of pads and to expose the plurality of pads; and
performing a cutting process on the wafer to form a plurality of dies.

12. The method for manufacturing a biosensor package structure as claimed in claim 11, wherein the plurality of pads are formed on a cutting line of the wafer.

13. The method for manufacturing a biosensor package structure as claimed in claim 8, prior to the step of removing the first carrier substrate, further comprising
patterning the protection layer to form a plurality of second openings that expose the redistribution layer.

14. The method for manufacturing a biosensor package structure as claimed in claim 8, after the step of removing the first carrier substrate, further comprising
coating a biomaterial over the biosensing region.
